(19) United States
(12) Patent Application Publication
(10) Pub. No.: US 2026/0206622 A1
(43) Pub. Date: Jul. 16, 2026

(54) ELECTRONIC PACKAGE AND SUBSTRATE STRUCTURE THEREOF

(71) Applicant: SILICONWARE PRECISION INDUSTRIES CO., LTD., Taichung City (TW)

(72) Inventors: Wen-We SU, Taichung City (TW); Szu-Hsien CHEN, Taichung City (TW)

(73) Assignee: SILICONWARE PRECISION INDUSTRIES CO., LTD., Taichung City (TW)

(21) Appl. No.: 19/263,360

(22) Filed: Jul. 8, 2025

(30) Foreign Application Priority Data
Jan. 16, 2025 (TW) 114101871

(51) Int. Cl. H01L 23/498; H01L 23/00; H01L 23/31

(52) U.S. Cl. CPC H10W 70/65; H10W 70/685; H10W 74/117; H10W 90/701; H10W 90/724

(57) ABSTRACT

The present application provides an electronic package and substrate structure thereof. The substrate structure includes an insulating layer, a wiring layer, a conductive via and an insulating protective layer. The conductive via is free from overlapping with an edge of an opening of the insulating protective layer. This is to avoid stress concentration on the insulating protective layer during a probe testing and to prevent the insulation protective layer from cracking.

### BACKGROUND

### 1. Technical Field

The present disclosure relates to a semiconductor packaging technology, and more particularly, to an electronic package and a substrate structure thereof that can improve reliability.

### 2. Description of Related Art

The electrical testing equipment currently used by packaging and testing facility at the packaging and testing stage is a standardized testing machine for testing semiconductor packages and end products thereof.

As shown in FIG. 1A, in the conventional testing operation, a semiconductor package 1 with ball grid array (BGA) specification is arranged on a probe card 9 to make the probes 90 of the probe card 9 contact the solder balls 19 on the lower side of the semiconductor package 1, and the probe card 9 transmits the test signal to the testing machine (not shown) through an external circuit. Hence, during testing, it is necessary to press down the upper side of the semiconductor package 1, so that each probe 90 can correspondingly contact the solder ball 19.

However, in the conventional semiconductor package 1, if the conductive via 102 of the substrate structure 10 and the edge of an opening 170 of a solder mask 17 for exposing an electrical contact pad 103 overlap with each other, as shown in FIG. 1B, the solder mask 17 is prone to stress concentration when the semiconductor package 1 is subjected to a probe testing (probe ball insertion), resulting in a crack K in the solder mask 17, especially if the conductive vias 102 of the substrate structure 10 are in a stacked via design, the stress concentration is more easily to occur.

Therefore, how to overcome the aforementioned problems of the prior art has become an urgent issue to be solved.

### SUMMARY

In view of the aforementioned shortcomings of the prior art, the present disclosure provides a substrate structure, which includes: an insulating layer; a wiring layer formed on the insulating layer and having at least an electrical contact pad; at least a conductive via formed in the insulating layer; and an insulating protective layer formed on the insulating layer and having an opening exposing the electrical contact pad, wherein a position of the conductive via is free from overlapping with an edge of the opening.

In the aforementioned substrate structure, the conductive via is completely located within the edge of the opening.

In the aforementioned substrate structure, the conductive via is completely located outside the edge of the opening. For example, an edge of the conductive via is correspondingly aligned with an edge of the electrical contact pad, the conductive via is completely located outside an edge of the electrical contact pad, or an edge of the conductive via is correspondingly aligned with the edge of the opening.

In the aforementioned substrate structure, the insulating layer is multi-layered, and a plurality of the conductive vias are formed in the insulating layer by adopting a stacked via design.

The present disclosure also provides an electronic package, which includes: the aforementioned substrate structure; and an electronic component disposed on the substrate structure to be electrically connected to the wiring layer.

In the aforementioned electronic package, further including a conductive component bonded to the electrical contact pad.

In the aforementioned electronic package, further including an encapsulation layer formed on the substrate structure to encapsulate the electronic component. For example, a conductive pillar is formed on the substrate structure to be electrically connected to the wiring layer, and the encapsulation layer encapsulates the conductive pillar. Further, a circuit structure is formed on the encapsulation layer and electrically connected to the conductive pillar.

It can be seen from the above that, in the electronic package and the substrate structure thereof of the present disclosure, the position of the conductive via is free from overlapping with the edge of an opening of the insulating protective layer to avoid stress concentration on the insulating protective layer during probe testing. Therefore, as compared to the prior art, the insulating protective layer of the present disclosure does not crack during the testing, thereby efficiently improving the reliability of the electronic package efficiently.

### BRIEF DESCRIPTION OF THE DRAWINGS

FIG. 1A is a schematic cross-sectional view showing a conventional semiconductor package during testing.

FIG. 1B is a schematic partial top view of FIG. 1A.

FIG. 2A is a schematic cross-sectional view showing an electronic package and substrate structure thereof of the present disclosure during testing.

FIG. 2B is a schematic partial top view of FIG. 2A.

FIG. 3 is a schematic partial cross-sectional view showing another embodiment of the electronic package and substrate structure thereof of the present disclosure.

FIG. 4A, FIG. 4B, FIG. 4C are schematic partial top views showing other embodiments of the electronic package and substrate structure thereof of the present disclosure.

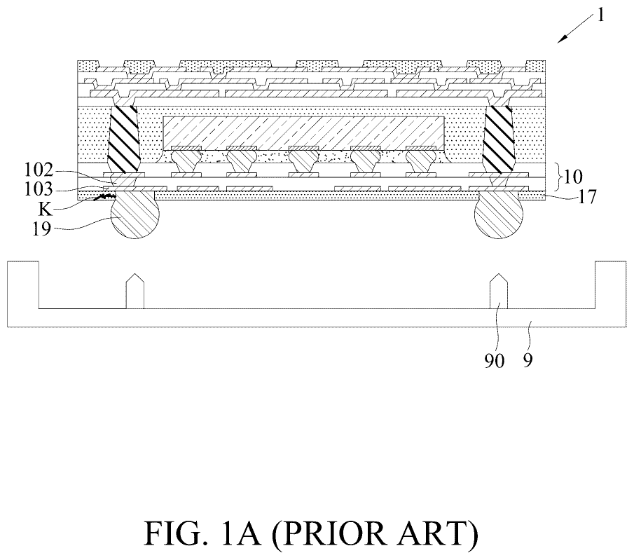

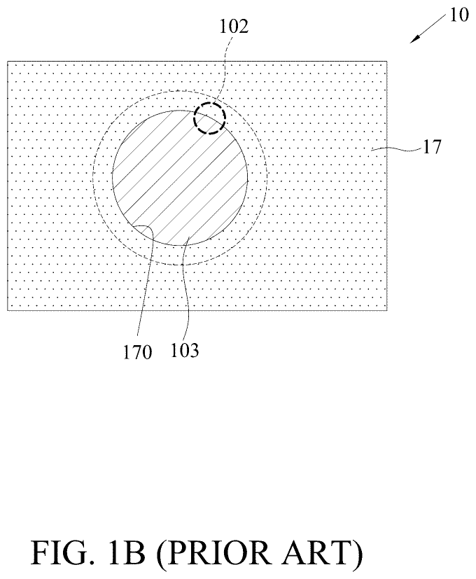

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a” and the like are merely for clear explanation rather than limiting the practicable scope of the present disclosure, and thus, alterations or adjustments of the relative relationships thereof without essentially altering the technical contents should still be considered in the practicable scope of the present disclosure.

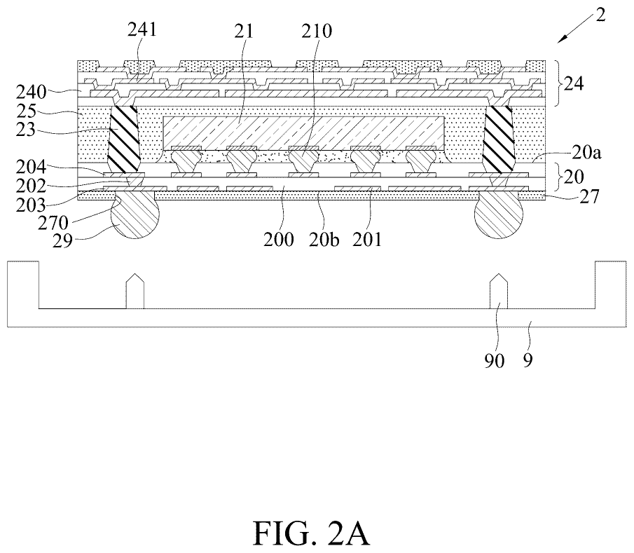

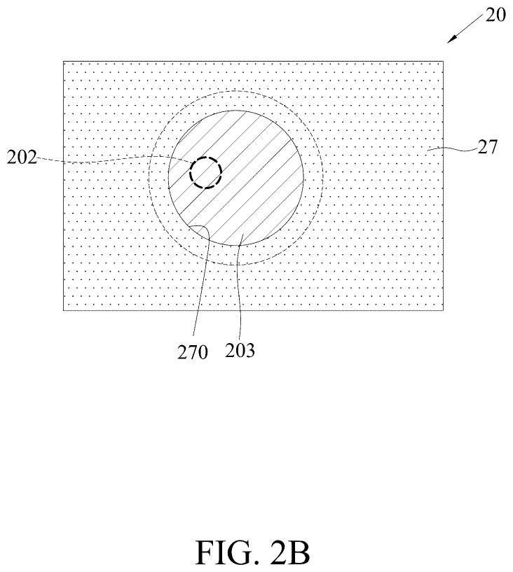

FIG. 2A is a schematic cross-sectional view showing an electronic package 2 of the present disclosure. As shown in FIG. 2A, the electronic package 2 includes: a substrate structure 20, at least an electronic component 21, a plurality of conductive pillars 23, an encapsulation layer 25, a circuit structure 24, and a plurality of conductive components 29.

The substrate structure 20 is, for example, a packaging substrate with a core layer or a coreless packaging substrate, which adopts the redistribution layer (RDL) specification. The substrate structure 20 includes an insulating layer 200, a wiring layer 201 formed on the insulating layer 200, and a plurality of conductive vias 202 formed in the insulating layer 200 and electrically connected to the wiring layer 201.

In an embodiment, the substrate structure 20 is defined to have a first side 20a and a second side 20b opposite to the first side 20a, and the wiring layers 201 at the first side 20a and the second side 20b respectively have a plurality of contacts 204 and a plurality of electrical contact pads 203.

Besides, an insulating protective layer 27 is formed on the insulating layer 200 at the second side 20b, and the insulating protective layer 27 has a plurality of openings 270, such that each of the plurality of electrical contact pads 203 is exposed from each of the plurality of openings 270. It should be understood that the outermost insulating layer 200 at the first side 20a can be used as a solder mask to expose the plurality of contacts 204.

Please refer to FIG. 2B, in an embodiment, the conductive via 202 is completely located within the edge of the opening 270 without overlapping with the edge of the opening 270.

Moreover, the wiring layer 201 is made of copper, and the insulating layer 200 is made of dielectric materials such as polybenzoxazole (PBO), polyimide (PI), prepreg (PP), and the insulating protective layer 27 is made of solder mask such as green paint, ink, etc.

The electronic component 21 is an active component, a passive component, or a combination thereof, etc., which is disposed on the first side 20a of the substrate structure 20, wherein the active component is, for example, a semiconductor chip, and the passive component is, for example, a resistor, a capacitor, and an inductor.

In an embodiment, the electronic component 21 is disposed on the contacts 204 in a flip-chip manner through a plurality of conductive bumps 210 (such as solder material) and electrically connected to the wiring layer 201. Alternatively, the electronic component 21 may be electrically connected to the contact 204 in a wire bonding manner through a plurality of bonding wires (not shown). The electronic component 21 can also directly contact the contacts 204. However, the manner in which the electronic component 21 is electrically connected to the substrate structure 20 is not limited to the above.

The conductive pillar 23 is formed on the contact 204 at the first side 20a of the substrate structure 20 to be electrically connected to the wiring layer 201.

In an embodiment, the conductive pillar 23 is, for example, a metal pillar such as a copper pillar. It should be understood that a solder ball can also be adopted as the conductive pillar 23, but it is not limited to the above.

The encapsulation layer 25 is an insulating material, which is formed on the first side 20a of the substrate structure 20 to encapsulate the electronic component 21 and the plurality of conductive pillars 23.

In an embodiment, the encapsulation layer 25 is an insulating material, such as polyimide (PI), dry film, molding compound such as epoxy. For example, the manufacturing process of the encapsulation layer 25 can be formed by liquid compound, injection, lamination, or compression molding.

The circuit structure 24 is formed on the encapsulation layer 25 and electrically connected to the plurality of conductive pillars 23.

In an embodiment, the circuit structure 24 includes a plurality of dielectric layers 240 and a plurality of circuit layers 241, such as the redistribution layer (RDL) specification, formed on the plurality of dielectric layers 240. The outermost dielectric layer 240 can serve as a solder mask, and the outermost circuit layer 241 is exposed from the solder mask for bonding to an electronic device (not shown). Alternatively, the circuit structure 24 may also only include a single dielectric layer 240 and a single circuit layer 241.

In addition, the circuit layer 241 is made of copper, and the dielectric layer 240 is made of dielectric material such as polybenzoxazole (PBO), polyimide (PI), prepreg (PP), etc., or solder mask such as green paint, ink, etc.

The conductive component 29 is a solder ball or a metal bump such as a copper bump, which is disposed on the electrical contact pad 203 of the substrate structure 20 and electrically connected to the wiring layer 201.

During the testing operation, the electronic package 2 is configured with its conductive components 29 on a probe card 9, making the probes 90 of the probe card 9 contact the conductive components 29, and the probe card 9 transmits the test signal to the testing machine (not shown) through an external circuit.

Hence, the electronic package 2 of the present disclosure mainly uses the conductive via 202 of the substrate structure 20 to be completely located within the edge of the opening 270 without overlapping the edge of the opening 270. During the testing (probe ball insertion) operation, when the electronic package 2 is pressed down, each probe 90 can correspondingly contact the conductive component 29 to avoid stress concentration on the insulating protective layer 27. Therefore, as compared to the prior art, the insulating protective layer 27 does not crack during the testing operation, thereby efficiently improving the reliability of the electronic package 2.

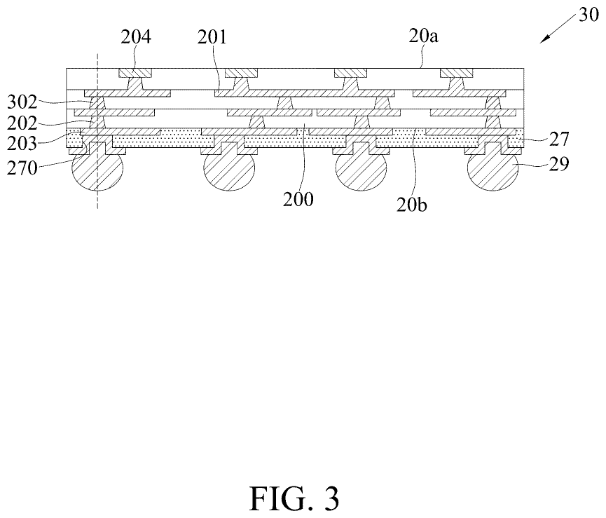

Please refer to FIG. 3, in another embodiment, the substrate structure 30 adopts the stacked via design to form conductive vias 202, 302 on each layer, and the stress concentration on the insulating protective layer 27 can also be efficiently avoided.

Furthermore, the electronic package 2 of the present disclosure not only improves the reliability of the electronic package 2, but also does not need to vary the appearance of the substrate structure, and which can be manufactured using existing semiconductor packaging process without developing special process or purchasing special equipment, thus it is beneficial to reduce the production costs of products.

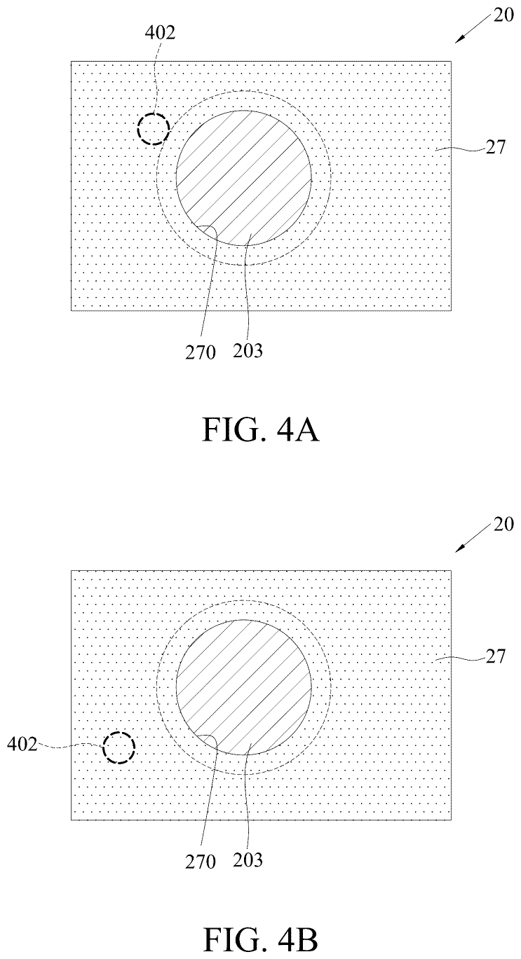

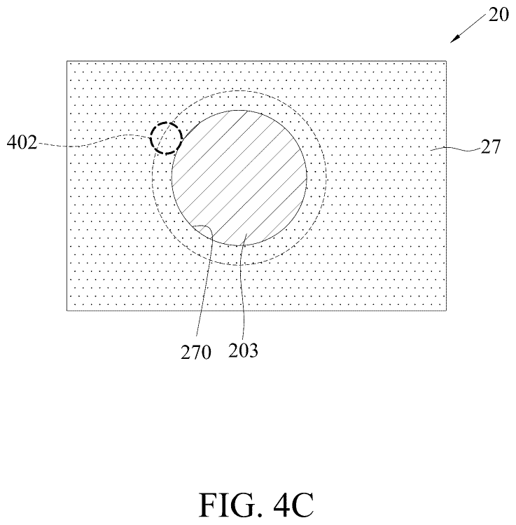

Additionally, in other embodiments, the conductive via 402 may also be located outside the edge of the opening 270 without overlapping the edge of the opening 270. For example, the edge of the conductive via 402 is correspondingly aligned with the edge of the electrical contact pad 203, as shown in FIG. 4A. Alternatively, the conductive via 402 is completely located outside the edge of the electrical contact pad 203, as shown in FIG. 4B, or the edge of the conductive via 402 is correspondingly aligned with the edge of the opening 270, as shown in FIG. 4C.

Therefore, the position of the conductive via can be set according to requirements, as long as it does not overlap the edge of the opening 270 of the insulating protective layer, and is not limited to the above.

To sum up, in the electronic package and the substrate structure thereof of the present disclosure, the position of the conductive via is free from overlapping with the edge of an opening of the insulating protective layer to avoid stress concentration on the insulating protective layer during probe testing. Therefore, the insulating protective layer of the present disclosure does not crack during the testing, thereby efficiently improving the reliability of the electronic package efficiently.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A substrate structure, comprising:
an insulating layer;
a wiring layer formed on the insulating layer and having at least an electrical contact pad;
at least a conductive via formed in the insulating layer; and
an insulating protective layer formed on the insulating layer and having an opening exposing the electrical contact pad, wherein a position of the conductive via is free from overlapping with an edge of the opening.

2. The substrate structure of claim 1, wherein the conductive via is completely located within the edge of the opening.

3. The substrate structure of claim 1, wherein the conductive via is completely located outside the edge of the opening.

4. The substrate structure of claim 3, wherein an edge of the conductive via is correspondingly aligned with an edge of the electrical contact pad.

5. The substrate structure of claim 3, wherein the conductive via is completely located outside an edge of the electrical contact pad.

6. The substrate structure of claim 3, wherein an edge of the conductive via is correspondingly aligned with the edge of the opening.

7. The substrate structure of claim 1, wherein the insulating layer is multi-layered, and a plurality of the conductive vias are formed in the insulating layer by adopting a stacked via design.

8. An electronic package, comprising:
the substrate structure of claim 1; and
an electronic component disposed on the substrate structure to be electrically connected to the wiring layer.

9. The electronic package of claim 8, further comprising a conductive component bonded to the electrical contact pad.

10. The electronic package of claim 8, further comprising an encapsulation layer formed on the substrate structure to encapsulate the electronic component.

11. The electronic package of claim 10, further comprising a conductive pillar formed on the substrate structure to be electrically connected to the wiring layer, and the encapsulation layer encapsulates the conductive pillar.

12. The electronic package of claim 11, further comprising a circuit structure formed on the encapsulation layer and electrically connected to the conductive pillar.

13. The electronic package of claim 8, wherein the conductive via is completely located within the edge of the opening.

14. The electronic package of claim 8, wherein the conductive via is completely located outside the edge of the opening.

15. The electronic package of claim 14, wherein an edge of the conductive via is correspondingly aligned with an edge of the electrical contact pad.

16. The electronic package of claim 14, wherein the conductive via is completely located outside an edge of the electrical contact pad.

17. The electronic package of claim 14, wherein an edge of the conductive via is correspondingly aligned with the edge of the opening.

18. The electronic package of claim 8, wherein the insulating layer is multi-layered, and a plurality of the conductive vias are formed in the insulating layer by adopting a stacked via design.
